(19) United States
(12) Patent Application Publication
(10) Pub. No.: US 2025/0259961 A1
(43) Pub. Date: Aug. 14, 2025

(54) SEMICONDUCTOR APPARATUS

(71) Applicant: Mitsubishi Electric Corporation, Tokyo (JP)

(72) Inventors: Kotaro NISHIHARA, Tokyo (JP); Taketoshi SHIKANO, Tokyo (JP); Yosuke NAKATA, Tokyo (JP)

(73) Assignee: Mitsubishi Electric Corporation, Tokyo (JP)

(21) Appl. No.: 19/002,455

(22) Filed: Dec. 26, 2024

(30) Foreign Application Priority Data
Feb. 9, 2024 (JP) 2024-018818

(51) Int. Cl. H01L 23/00; H01L 23/31; H01L 23/498

(52) U.S. Cl. CPC H01L 24/37; H01L 23/49811; H01L 24/40; H01L 23/3107; H01L 2224/3701; H01L 2224/40137; H01L 2224/40225

(57) ABSTRACT

A semiconductor apparatus according to the present disclosure includes: a substrate including an electrode land; a semiconductor device mounted on the substrate and connected to the electrode land; a plate-like lead frame having one end connected to the semiconductor device or the electrode land; and a sealing material configured to seal the semiconductor device, the substrate, and the lead frame. Inside the sealing material, adjacent linear portions of the lead frame that form ridges and valleys in side view are folded back at an angle smaller than 180 degrees.

### BACKGROUND OF THE INVENTION

### Field

The present disclosure relates to a semiconductor apparatus.

### Background

A technique for using a plate-like lead frame as wiring joined to a surface electrode of a semiconductor device to realize a large area is known. As compared with a wire conventionally used, joining strength with the semiconductor device can be enhanced, and heat dispersion can also be increased. Thus, it is possible to prolong the power cycle life of the semiconductor apparatus.

However, thermal expansion/contraction difference may occur among parts such as a substrate, the semiconductor device, the lead frame, and a sealing material, due to heat applied during manufacture, and these parts may be warped due to generation of residual stress.

JP 2017-174927 A discloses a structure including, in order to relax stress, a spring part having a wave shape that is formed by vertically folding back a lead frame by 180 degrees. Expansion/contraction of the spring part can absorb the thermal expansion/contraction difference among the parts. This makes it possible to suppress occurrence of warpage.

In the above-described method, however, it is necessary to fold back the lead frame by 180 degrees in order to shape the lead frame into the wave shape. Thus, force is necessary in machining.

### SUMMARY

To solve the above-described issue, an object of the present disclosure is to provide a semiconductor apparatus that includes a lead frame having a shape for relaxing stress and can reduce force applied during formation of the lead frame.

The features and advantages of the present disclosure may be summarized as follows.

According to an aspect of the present disclosure, a semiconductor apparatus comprises a substrate including an electrode land; a semiconductor device mounted on the substrate and connected to the electrode land; a plate-like lead frame having one end connected to the semiconductor device or the electrode land; and a sealing material configured to seal the semiconductor device, the substrate, and the lead frame, wherein inside the sealing material, adjacent linear portions of the lead frame that form ridges and valleys in side view are folded back at an angle smaller than 180 degrees.

According to another aspect of the present disclosure, a semiconductor apparatus comprises a substrate including an electrode land; a semiconductor device mounted on the substrate and connected to the electrode land; a plate-like lead frame having one end connected to the semiconductor device or the electrode land; and a sealing material configured to seal the semiconductor device, the substrate, and the lead frame, wherein inside the sealing material, the lead frame includes a U-shaped loop part in top view, or has a zigzag shape or a step shape in top view.

Other and further objects, features and advantages of the invention will appear more fully from the following description.

### BRIEF DESCRIPTION OF DRAWINGS

FIG. 1 is a side view of a semiconductor apparatus according to a first embodiment of the present disclosure.

FIG. 2 is a side view of the lead frame according to the first embodiment.

FIG. 3 illustrates a modification of the semiconductor apparatus according to the first embodiment.

FIG. 4 illustrates another modification of the semiconductor apparatus according to the first embodiment.

FIG. 5 is a top view of the semiconductor apparatus according to the second embodiment of the present disclosure.

FIG. 6 is a side view of the semiconductor apparatus according to the second embodiment of the present disclosure.

FIG. 7 is a top view of the semiconductor apparatus according to a third embodiment of the present disclosure.

FIG. 8 is a shape pattern of the lead frame according to the third embodiment.

FIG. 9 is a shape pattern of the lead frame according to the third embodiment.

FIG. 10 is a shape pattern of the lead frame according to the third embodiment.

FIG. 11 is a shape pattern of the lead frame according to the third embodiment.

FIG. 12 is a top view of the semiconductor apparatus obtained by combining the first to third embodiments.

### DESCRIPTION OF EMBODIMENTS

A semiconductor apparatus according to the embodiments of the present disclosure will be described with reference to the drawings. The same components will be denoted by the same symbols, and the repeated description thereof may be omitted.

### First Embodiment

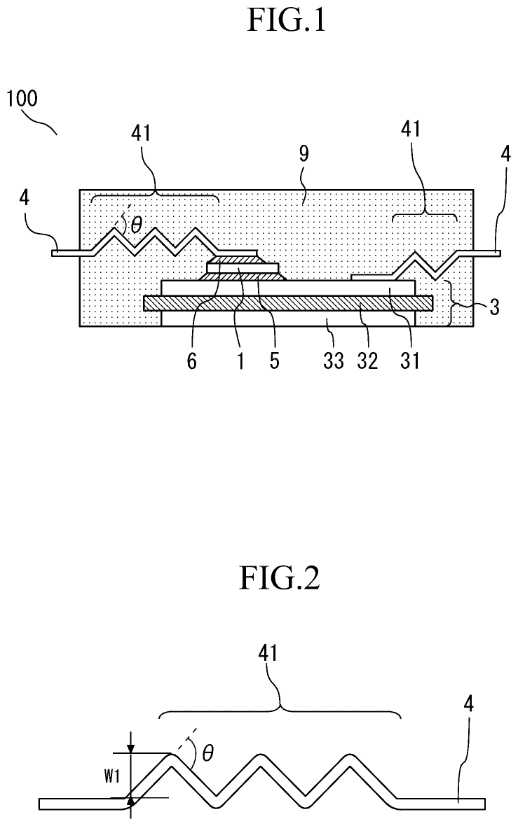

FIG. 1 is a side view of a semiconductor apparatus 100 according to a first embodiment of the present disclosure. The semiconductor apparatus 100 includes a semiconductor device 1, a substrate 3 on which the semiconductor device 1 is mounted, a plate-like lead frame 4, joining materials 5 and 6, and a sealing material 9 sealing these members.

The substrate 3 includes an electrode land 31, an insulation layer 32, and a substrate heat dissipation layer 33, and performs switching control of the semiconductor device 1. The electrode land 31 is an electrode layer of the substrate 3. When a metal material having high thermal conductivity is used as the electrode land 31, heat dissipation can be improved.

The insulation layer 32 is disposed between the electrode land 31 and the substrate heat dissipation layer 33, and insulates the electrode land 31 and the substrate heat dissipation layer 33 from each other. When a resin enduring deformation is used as the insulation layer 32, it is possible to suppress occurrence of cracks even if minute deformation occurs on a member due to power cycle or the like. The material of the insulation layer 32 is not limited to the resin, and AlN, Al₂O₃, Si₃N₄, or other materials may be used.

When a material having high thermal conductivity is used for the substrate heat dissipation layer 33, heat dissipation of the electrode land 31 can be improved through the insulation layer 32, and temperature increase of the semiconductor apparatus 100 can be suppressed.

The semiconductor device 1 is electrically connected onto the electrode land 31 by the joining material 5. The semiconductor device 1 is, for example, a reverse conducting insulated gate bipolar transistor (RC-IGBT) made of Si, or a metal-oxide-semiconductor field effect transistor (MOSFET) made of SiC.

The joining material 5 is disposed between the semiconductor device 1 and the electrode land 31. The joining material 6 is disposed between the semiconductor device 1 and the lead frame 4. The joining materials 5 and 6 are preferably members high in electric conductivity and thermal conductivity, and solder, silver, or the like is used. Lead-free solder has a role of a buffer reducing stress in addition to the above-described characteristics, and using the lead-free solder makes it possible to improve reliability of the semiconductor apparatus 100. Alternatively, sintered silver may be used.

The sealing material 9 seals the semiconductor device 1, the substrate 3, the lead frame 4, and the like. A material of the sealing material 9 is desirably a material that can improve reliability of the semiconductor apparatus 100. For example, a thermosetting epoxy resin filled with SiO₂ filler is used. As a sealing method, for example, a transfer molding method is used.

The lead frame 4 is a plate-like metal, and one end thereof is electrically connected to a control electrode such as a gate electrode of the semiconductor device 1, an emitter electrode, or a collector electrode. Alternatively, the one end is electrically connected to the electrode land 31.

The other end of the lead frame 4 connected to neither the semiconductor device 1 nor the electrode land 31 extends to outside of the sealing material 9. To relax stress, the lead frame 4 includes a spring part 41 having a zigzag shape inside the sealing material 9.

More specifically, at the spring part 41 having the zigzag shape, the lead frame 4 is folded back so as to form ridges and valleys in side view, and a folding angle θ between adjacent linear portions forming a ridge or a valley is smaller than 180 degrees. In terms of reduction in folding force, the angle θ is more preferably 90 degrees or less as illustrated in the drawing.

As machining for the spring part 41, a bending work of a metal plate is common, but a pressing work using a die or the like may be used.

As described above, the spring part in the existing technique has a wave shape, and force is necessary in machining because it is necessary to fold back the lead frame 4 by 180 degrees. On the other hand, when the spring part 41 is formed in a zigzag shape as in the present disclosure, force applied in machining can be reduced. When the number of repetitions that is the number of windings of the spring is the same, a volume of the metal as a base material in the case of the zigzag shape can be reduced as compared with the case of the wave shape. This makes it possible to reduce electric resistance of the lead frame, and to reduce a manufacturing cost.

FIG. 2 is a side view of the lead frame 4 according to the first embodiment. To increase deflection of the spring, a height W1 of the ridge is preferably secured to be a plate thickness or more. The function as the spring can be exerted when one or more ridges and one or more valleys are provided.

As describe above, the lead frame 4 according to the present embodiment includes the spring part 41 having a zigzag shape. The lead frame 4 at the spring part 41 is folded back so as to form ridges and valleys in side view, and the folding angle θ between adjacent linear portions forming a ridge or a valley is smaller than 180 degrees. This makes it possible to reduce force applied in machining.

The semiconductor device 1 is not limited to a semiconductor device made of silicon, and may be formed by a wide bandgap semiconductor having a bandgap greater than a bandgap of silicon. Examples of the wide bandgap semiconductor include silicon carbide, a gallium nitride material, and diamond. The semiconductor device 1 formed by such a wide bandgap semiconductor can be downsized because of high withstand voltage and high allowable current density. Using the downsized semiconductor device 1 makes it possible to downsize and highly integrate the semiconductor apparatus 100 in which the semiconductor device 1 is incorporated. Further, since the semiconductor device 1 has high heat resistance, a heat dissipation fin of a heatsink can be downsized, and a water-cooling unit can be substituted with an air-cooling unit. This makes it possible to further downsize the semiconductor apparatus 100. The semiconductor device 1 is low in power loss and high in efficiency. Thus, the semiconductor apparatus 100 can be increased in efficiency. Note that the whole of the semiconductor device 1 is desirably formed by the wide bandgap semiconductor; however, the semiconductor device 1 may be partially formed by the wide bandgap semiconductor, and effects described in the present embodiment are achievable. This is true of all embodiments described below.

### [First Modification]

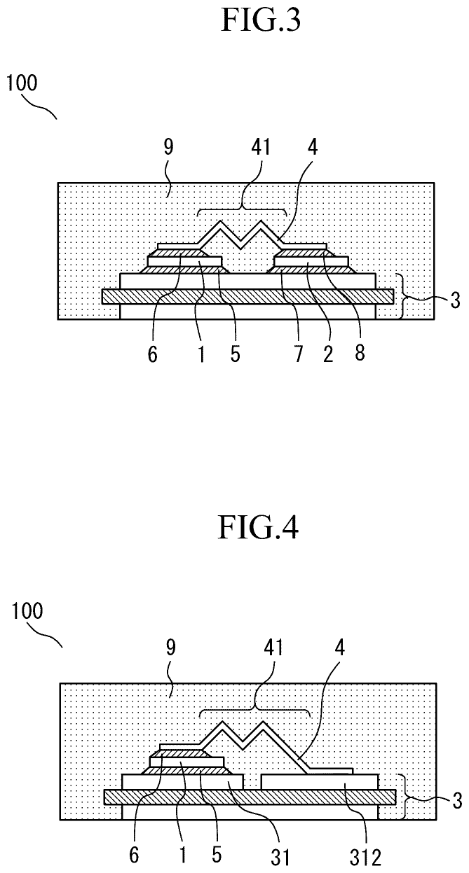

FIG. 3 illustrates a modification of the semiconductor apparatus 100 according to the first embodiment. The one end of the lead frame 4 not connected to the semiconductor device 1 is connected to another semiconductor device 2 inside the sealing material 9. The lead frame 4 connecting the two semiconductor devices 1 and 2 as illustrated may include the spring part 41 having a zigzag shape. As a result, effects similar to the effects by the first embodiment are achievable.

### [Second Modification]

FIG. 4 illustrates another modification of the semiconductor apparatus 100 according to the first embodiment. The one end of the lead frame 4 not connected to the semiconductor device 1 is connected to another electrode land 312 on which the semiconductor device 1 is not mounted, on the substrate 3. The lead frame 4 connecting the semiconductor device 1 and the substrate 3 in the above-described manner may include the spring part 41 having a zigzag shape. As a result, effects similar to the effects by the first embodiment are achievable.

### Second Embodiment

In the present embodiment, a through hole 43 into which the joining material 6 is poured is provided at a front end of the lead frame 4 connected to the semiconductor device 1. In the following, matters changed from the first embodiment are described.

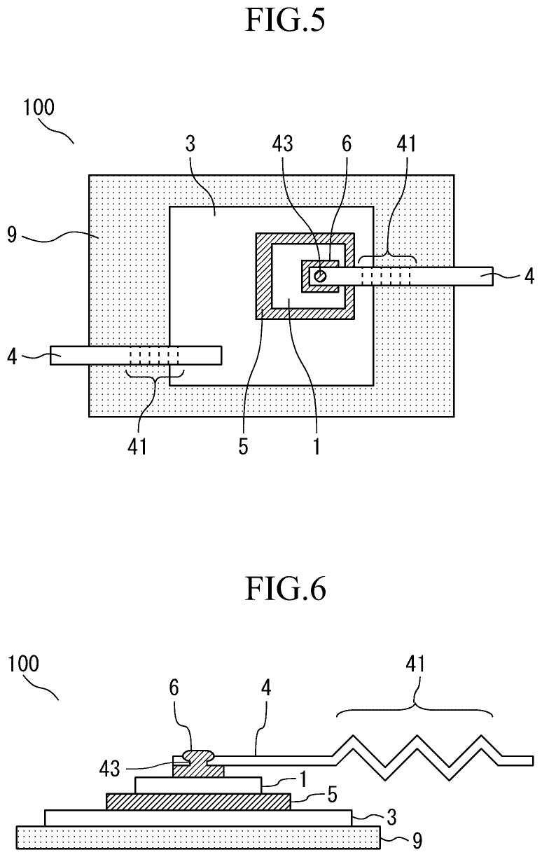

FIG. 5 is a top view of the semiconductor apparatus 100 according to the second embodiment of the present disclosure. The lead frame 4 includes the through hole 43 penetrating through the lead frame 4 from an upper surface to a surface connected to the semiconductor device 1. In joining, the joining material 6 is poured into the through hole 43. In joining of the semiconductor device 1 and the lead frame 4, a method in which a solder foil is inserted between the semiconductor device 1 and the lead frame 4, and the semiconductor device 1 and the lead frame 4 are soldered while being positioned is generally used. When the joining material 6 is poured into the through hole 43 as in the present disclosure, it is unnecessary to simultaneously position three members, namely, the semiconductor device 1, the solder foil, and the lead frame 4, and the joining is easily performable.

FIG. 6 is a side view of the semiconductor apparatus 100 according to the second embodiment of the present disclosure. The joining material 6 between the lead frame 4 and the semiconductor device 1 passes through the through hole 43, and is swelled on the upper surface of the lead frame 4. Increasing a contact area of the joining material 6 and the lead frame 4 in the above-described manner makes it possible to firmly fix the semiconductor device 1 and the lead frame 4, as compared with a common lead frame including no through hole 43.

### Third Embodiment

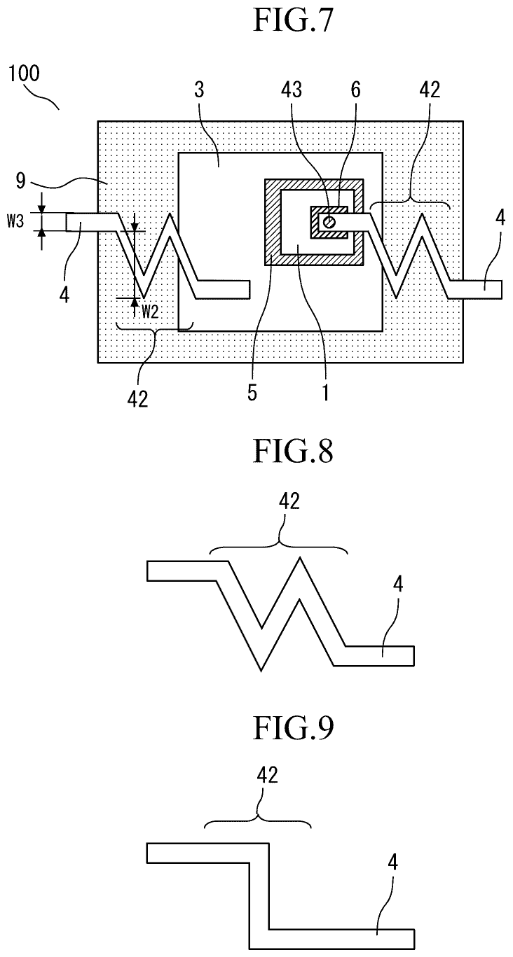

FIG. 7 is a top view of the semiconductor apparatus 100 according to a third embodiment of the present disclosure. To relax stress, the lead frame 4 according to the present embodiment includes a spring part 42 having a zigzag shape in top view. In other words, in the spring part 42, ridges and valleys each having a V-shape are repeatedly provided in top view. To form the spring part 42 according to the present embodiment, it is unnecessary to fold the lead frame 4 unlike the lead frame 4 according to the first embodiment. Therefore, the spring part 42 can be machined by punching with a die or the like, and force applied in machining can be reduced.

The spring part 42 according to the present embodiment has a large cross-sectional secondary moment as compared with the first embodiment. Therefore, an expansion/contraction effect is small. To increase deflection of the spring, a deformation amount W2 desirably has a value sufficiently greater than a plate width W3.

FIGS. 8 to 11 are top views of the lead frame 4 each illustrating a shape pattern of the lead frame 4 according to the third embodiment. FIG. 8 illustrates the zigzag shape same as illustrated in FIG. 7. Therefore, description of the shape is omitted. The lead frame 4 may be bent into a step shape in top view as illustrated in FIG. 9. Note that the number of steps is not limited.

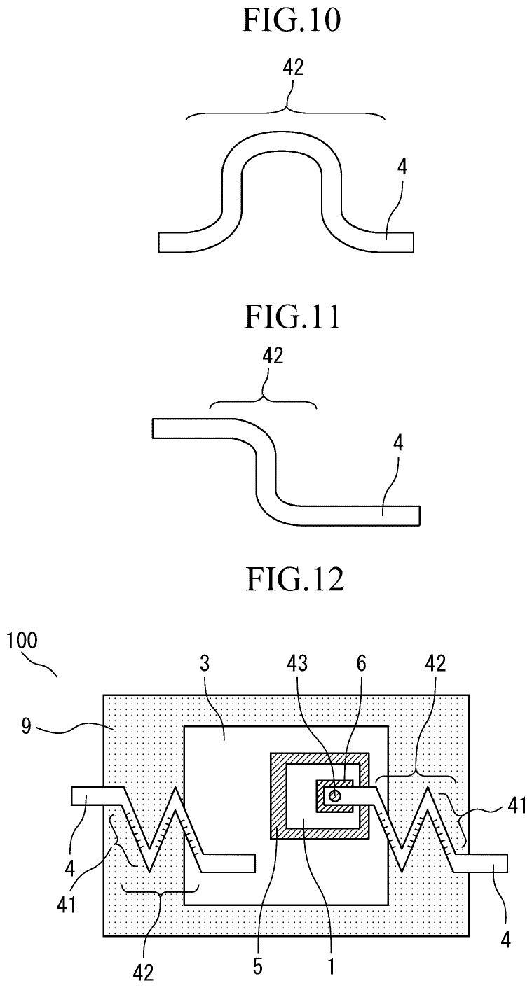

The lead frame 4 may include a U-shaped loop part in top view as illustrated in FIG. 10. A corner as a folded-back part of the U-shape is formed with a curved line. Therefore, as compared with the zigzag shape illustrated in FIG. 8, stress concentrating on the corner can be relaxed. The spring part 42 having a wave shape may be formed by continuously arranging loops.

In FIG. 11, the lead frame 4 has a step shape in top view as in FIG. 9, but a bent part of the step is formed with a curved line. In other words, the bent part of the step has been subjected to rounding, R chamfering, and the like. As compared with FIG. 9, an effect of relaxing stress at the corner is expected. Even in the zigzag shape illustrated in FIG. 8, the folded-back parts of the zigzag shape may be formed with a curved line.

As described above, in the present embodiment, the spring part 42 that has the zigzag shape, the step shape, or the U-shaped loop in top view is provided. Therefore, stress can be relaxed as in the first embodiment. Further, force applied in machining of the spring part 42 can be further reduced as compared with the first embodiment.

As described above, according to the present disclosure, it is possible to provide the semiconductor apparatus that includes the lead frame having the shape for relaxing stress and can reduce force applied during formation of the lead frame.

The present disclosure is not limited to the above-described embodiments, and can be variously modified without departing from the spirit in implementation. Further, the embodiments can be implemented in combination as appropriate. In this case, combined effects are achievable. For example, FIG. 12 is a top view of the semiconductor apparatus 100 obtained by combining the first to third embodiments. As a result, combined effects of the first to third embodiments are achievable.

Hereinafter, various aspects of the present disclosure will be collectively described as appendixes.

### (Appendix 1)

A semiconductor apparatus comprising:
a substrate including an electrode land;
a semiconductor device mounted on the substrate and connected to the electrode land;
a plate-like lead frame having one end connected to the semiconductor device or the electrode land; and
a sealing material configured to seal the semiconductor device, the substrate, and the lead frame, wherein
inside the sealing material, adjacent linear portions of the lead frame that form ridges and valleys in side view are folded back at an angle smaller than 180 degrees.

### (Appendix 2)

The semiconductor apparatus according to appendix 1, wherein, inside the sealing material, the adjacent linear portions of the lead frame are folded back at an angle smaller than 90 degrees.

### (Appendix 3)

A semiconductor apparatus comprising:
a substrate including an electrode land;
a semiconductor device mounted on the substrate and connected to the electrode land;
a plate-like lead frame having one end connected to the semiconductor device or the electrode land; and
a sealing material configured to seal the semiconductor device, the substrate, and the lead frame, wherein
inside the sealing material, the lead frame
includes a U-shaped loop part in top view, or
has a zigzag shape or a step shape in top view.

### (Appendix 4)

The semiconductor apparatus according to any one of appendixes 1 to 3, wherein
the one end of the lead frame is connected to the semiconductor device, and
another end of the lead frame is connected to another semiconductor device or another electrode land inside the sealing material, or extends to outside of the sealing material.

### (Appendix 5)

The semiconductor apparatus according to any one of appendixes 1 to 4, wherein
the one end of the lead frame is connected to the semiconductor device,
the one end of the lead frame includes a through hole penetrating through the lead frame from an upper surface to a surface connected to the semiconductor device, and a joining material joining the one end of the lead frame and the semiconductor device passes through the through hole and is swelled on the upper surface.

### (Appendix 6)

The semiconductor apparatus according to any one of appendixes 1 to 5, wherein the semiconductor device is formed by a wide bandgap semiconductor.

### (Appendix 7)

The semiconductor apparatus according to any one of appendixes 3 to 6, wherein the lead frame has a step shape in top view, and a bent part of the step is formed with a curved line.

### (Appendix 8)

The semiconductor apparatus according to any one of appendixes 3 to 6, wherein the lead frame has a zigzag shape in top view, and a folded-back part of the zigzag shape is formed with a curved line.

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2024-18818, filed on Feb. 9, 2024 including specification, claims, drawings and summary, on which the convention priority of the present application is based, is incorporated herein by reference in its entirety.

1. A semiconductor apparatus comprising:
a substrate including an electrode land;
a semiconductor device mounted on the substrate and connected to the electrode land;
a plate-like lead frame having one end connected to the semiconductor device or the electrode land; and
a sealing material configured to seal the semiconductor device, the substrate, and the lead frame, wherein
inside the sealing material, adjacent linear portions of the lead frame that form ridges and valleys in side view are folded back at an angle smaller than 180 degrees.

2. The semiconductor apparatus according to claim 1, wherein, inside the sealing material, the adjacent linear portions of the lead frame are folded back at an angle smaller than 90 degrees.

3. A semiconductor apparatus comprising:
a substrate including an electrode land;
a semiconductor device mounted on the substrate and connected to the electrode land;
a plate-like lead frame having one end connected to the semiconductor device or the electrode land; and
a sealing material configured to seal the semiconductor device, the substrate, and the lead frame, wherein
inside the sealing material, the lead frame
includes a U-shaped loop part in top view, or
has a zigzag shape or a step shape in top view.

4. The semiconductor apparatus according to claim 1, wherein
the one end of the lead frame is connected to the semiconductor device, and
another end of the lead frame is connected to another semiconductor device or another electrode land inside the sealing material, or extends to outside of the sealing material.

5. The semiconductor apparatus according to claim 2, wherein
the one end of the lead frame is connected to the semiconductor device, and
another end of the lead frame is connected to another semiconductor device or another electrode land inside the sealing material, or extends to outside of the sealing material.

6. The semiconductor apparatus according to claim 3, wherein
the one end of the lead frame is connected to the semiconductor device, and
another end of the lead frame is connected to another semiconductor device or another electrode land inside the sealing material, or extends to outside of the sealing material.

7. The semiconductor apparatus according to claim 1, wherein
the one end of the lead frame is connected to the semiconductor device,
the one end of the lead frame includes a through hole penetrating through the lead frame from an upper surface to a surface connected to the semiconductor device, and
a joining material joining the one end of the lead frame and the semiconductor device passes through the through hole and is swelled on the upper surface.

8. The semiconductor apparatus according to claim 2, wherein
the one end of the lead frame is connected to the semiconductor device,
the one end of the lead frame includes a through hole penetrating through the lead frame from an upper surface to a surface connected to the semiconductor device, and
a joining material joining the one end of the lead frame and the semiconductor device passes through the through hole and is swelled on the upper surface.

9. The semiconductor apparatus according to claim 3, wherein
the one end of the lead frame is connected to the semiconductor device,
the one end of the lead frame includes a through hole penetrating through the lead frame from an upper surface to a surface connected to the semiconductor device, and
a joining material joining the one end of the lead frame and the semiconductor device passes through the through hole and is swelled on the upper surface.

10. The semiconductor apparatus according to claim 1, wherein the semiconductor device is formed by a wide bandgap semiconductor.

11. The semiconductor apparatus according to claim 2, wherein the semiconductor device is formed by a wide bandgap semiconductor.

12. The semiconductor apparatus according to claim 3, wherein the semiconductor device is formed by a wide bandgap semiconductor.

13. The semiconductor apparatus according to claim 3, wherein the lead frame has a step shape in top view, and a bent part of the step is formed with a curved line.

14. The semiconductor apparatus according to claim 3, wherein the lead frame has a zigzag shape in top view, and a folded-back part of the zigzag shape is formed with a curved line.
